(19) United States
(12) Patent Application Publication
(10) Pub. No.: US 2017/0062410 A1
(43) Pub. Date: Mar. 2, 2017

(54) CIRCUIT INCLUDING A RECTIFYING ELEMENT, AN ELECTRONIC DEVICE INCLUDING A DIODE AND A PROCESS OF FORMING THE SAME

(71) Applicant: Semiconductor Components Industries, LLC, Phoenix, AZ (US)

(72) Inventor: Gary H. LOECHELT, Tempe, AZ (US)

(73) Assignee: Semiconductor Components Industries, LLC, Phoenix, AZ (US)

(21) Appl. No.: 14/841,530

(22) Filed: Aug. 31, 2015

(51) Int. Cl. H01L 27/06; H01L 29/866; H01L 21/306; H01L 29/78; H01L 21/8234; H01L 29/66; H01L 49/02; H01L 29/872

(52) U.S. Cl. CPC H01L 27/0629; H01L 28/60; H01L 29/866; H01L 29/872; H01L 29/78; H01L 21/8234; H01L 29/66143; H01L 29/66106; H01L 21/30604; H01L 29/66568

(57) ABSTRACT

A circuit can include a transistor, a capacitive element, and a rectifying element. The rectifying element and the capacitive element can be serially connected and coupled to the current-carrying terminals of the transistor. An electronic device may include part of the circuit. The electronic device can include a diode that includes a horizontally-oriented semiconductor member and a vertically-oriented semiconductor member having different conductivity types. The ends of the horizontally-oriented semiconductor and vertically-oriented semiconductor members physically contact each other. A process of forming an electronic device can include forming a semiconductor layer and forming a second semiconductor member. In a finished device, a diode includes a junction between dopants of first and second conductivity types within the semiconductor layer, within the semiconductor member, or at an interface between the semiconductor layer and the semiconductor member.

### FIELD OF THE DISCLOSURE

The present disclosure relates to circuits, electronic devices, and processes of forming electronic devices, and more particularly to circuits that include rectifying elements, electronic devices including diodes, and processes of forming the same.

### RELATED ART

An insulated gate field-effect transistor (IGFET) is a common type of transistor that can be used in power switching circuits. The IGFET includes a source region, a drain region, a channel region extending between the source and drain regions, and a gate structure adjacent to the channel region. The gate structure includes a gate electrode disposed adjacent to and separated from the channel region by a gate dielectric layer.

For a high frequency power converter, energy stored in parasitic inductance creates excessive voltage swings in a power loop. The voltage swings stress the avalanche capabilities of the switching devices, disrupt driver logic, and reduce overall efficiency. Improved performance of such power converters is desired.

### BRIEF DESCRIPTION OF THE DRAWINGS

Embodiments are illustrated by way of example and are not limited in the accompanying figures.

FIG. 1 includes a circuit schematic of a power converter in accordance with an embodiment.

FIG. 2 includes a circuit schematic of a power converter in accordance with an alternative embodiment.

FIG. 3 includes the circuit schematic of FIG. 1 at a first operating point.

FIG. 4 includes the circuit schematic of FIG. 1 at a second operating point.

FIG. 5 includes the circuit schematic of FIG. 1 at a third operating point.

FIG. 6 includes the circuit schematic of FIG. 1 at a fourth operating point.

FIG. 7 includes the circuit schematic of FIG. 1 at a fifth operating point.

FIG. 8 includes the circuit schematic of FIG. 1 at a sixth operating point.

FIG. 9 includes an illustration of a cross-sectional view of a portion of a workpiece including a buried conductive region, a buried insulating layer, a semiconductor layer, and a dielectric layer.

FIG. 10 includes an illustration of a cross-sectional view of the workpiece of FIG. 9 after forming a horizontally-oriented doped region and a resurf region.

FIG. 11 includes an illustration of a cross-sectional view of the workpiece of FIG. 10 after forming an insulating layer and a conductive layer.

FIG. 12 includes an illustration of a cross-sectional view of the workpiece of FIG. 11 after forming insulating members, patterning the conductive layer to form conductive electrode members, insulating sidewall spacers, and deep body doped regions.

FIG. 13 includes an illustration of a cross-sectional view of the workpiece of FIG. 12 after forming body regions, gate electrodes, an insulating layer, and source regions.

FIG. 14 includes an illustration of a cross-sectional view of the workpiece of FIG. 13 after forming a patterned interlevel dielectric layer and forming conductive electrode members within openings defined by the patterned interlevel dielectric layer.

FIG. 15 includes an illustration of a cross-sectional view of the workpiece of FIG. 14 after forming insulating spacers and trenches extending to the buried conductive region.

FIG. 16 includes an illustration of a cross-sectional view of the workpiece of FIG. 15 after forming conductive plugs within the trenches.

FIG. 17 includes an illustration of a cross-sectional view of the workpiece of FIG. 16 after forming another interlevel dielectric layer.

FIG. 18 includes an illustration of a cross-sectional view of the workpiece of FIG. 17 after patterning the interlevel dielectric layers and recessing gate and conductive electrode members to define contact openings to the conductive electrodes and the gate electrodes.

FIG. 19 includes an illustration of a cross-sectional view of the workpiece of FIG. 18 after patterning the other interlevel dielectric layer to define a contact opening extending to one of the body regions and forming a heavily doped region along a bottom of such opening.

FIG. 20 includes an illustration of cross-sectional views of the workpiece of FIG. 19 after forming conductive plugs within the contact openings.

FIG. 21 includes an illustration of a cross-sectional view of the workpiece of FIG. 20 after forming a first level of interconnects.

FIG. 22 includes an illustration of a cross-sectional view of a workpiece that includes an embodiment that includes a vertical transistor, a conductive electrode, and a zener diode.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

As used herein, the terms “horizontally-oriented” and “vertically-oriented,” with respect to a region, member, or structure, refer to the principal direction in which current flows through such region, member or structure. More specifically, current can flow through a region, member, or structure in a vertical direction, a horizontal direction, or a combination of vertical and horizontal directions. If current flows through a region, member, or structure in a vertical direction or in a combination of directions, wherein the vertical component is greater than the horizontal component, such a region, member, or structure will be referred to as vertically oriented. Similarly, if current flows through a region, member, or structure in a horizontal direction or in a combination of directions, wherein the horizontal component is greater than the vertical component, such a region, member, or structure will be referred to as horizontally oriented.

The term “metal” or any of its variants is intended to refer to a material that includes an element that is within any of the Groups 1 to 12, within Groups 13 to 16, an element that is along and below a line defined by atomic numbers 13 (Al), 31 (Ga), 50 (Sn), 51 (Sb), and 84 (Po). Metal does not include Si or Ge.

The term “normal operation” and “normal operating state” refer to conditions under which an electronic component or device is designed to operate. The conditions may be obtained from a data sheet or other information regarding voltages, currents, capacitance, resistance, or other electrical parameters. Thus, normal operation does not include operating an electrical component or device well beyond its design limits.

The term “power transistor” is intended to mean a transistor that is designed to normally operate with at least a 10 V difference maintained between the source and drain or emitter and collector of the transistor when the transistor is in an off-state. For example, when the transistor is in an off-state, a 10 V may be maintained between the source and drain without a junction breakdown or other undesired condition occurring.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

Group numbers corresponding to columns within the Periodic Table of Elements based on the IUPAC Periodic Table of Elements, version dated Jan. 21, 2011.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

A circuit can include a transistor, a capacitive element, and a rectifying element, wherein the capacitive element and rectifying element are serially connected. The transistor can include a current-carrying terminal coupled to an electrode of the capacitive element, and the other current-carrying terminal coupled to an anode of the rectifying element. The cathode of the rectifying element is coupled to the other electrode of the capacitive element.

In an embodiment, the circuit can be a power converter that includes a high-side transistor and a low-side transistor coupled to each other at an output node. A circuit can be used to provide energy to a load coupled to the output node. The circuit can further include a high-side capacitive element coupled to the high-side transistor and a low-side capacitive element coupled to the low-side transistor. The circuit can further include a rectifying element that is coupled to a current-carrying electrode of a transistor and an electrode of its corresponding capacitive element. In a particular embodiment, the rectifying element is a zener or Schottky diode, having its anode coupled to the current-carrying electrode of a transistor that is coupled to a power supply terminal and its cathode coupled to a power-supply-side electrode of its corresponding capacitive element. As used in this specification, for the capacitive elements, the electrode more closely coupled to a power supply terminal is referred to as the power-supply-side electrode, and the electrode more closely coupled to the output node is referred to as the output-side electrode.

In a physical implementation, the electronic device can include a diode that includes a horizontally-oriented semiconductor member and a vertically-oriented conductive member. The horizontally-oriented semiconductor member has an end and a particular conductivity type, and the vertically-oriented semiconductor member has an end and a different conductivity type. The ends of the horizontally-oriented semiconductor member and the vertically-oriented semiconductor member physically contact each other.

The circuit and electronic device can be useful to reduce voltage overshoot at the output node and allow more energy to be sent to the load during switching operations. The rectifying element modifies the resonant characteristics of the circuit. Because of its asymmetrical current carrying properties, the rectifying element can damp the resonant circuit during a low-to-high transition of the output node while still allowing for an efficient recovery of energy stored on the capacitive element during a high-to-low transition of the output node.

FIG. 1 includes a schematic diagram of a circuit 100 that can be used as a high frequency power converter. In the embodiment illustrated, the circuit includes a high-side switch and a low-side switch. The high-side switch includes a high-side transistor 112 that has an associated pn diode between its current-carrying terminals. The pn diode can be characterized by a drain-to-source breakdown voltage of the transistor 112. The low-side switch includes a low-side transistor 132 that has an associated pn diode between its current-carrying terminals. The pn diode can be characterized by a drain-to-source breakdown voltage of the transistor 132. In an embodiment, the transistors 112 and 132 can be insulated gate field-effect transistors. In another embodiment, the high-side switch, the low-side switches, or both switches can be bipolar transistors, and the pn diodes can be characterized by collector-to-emitter breakdown voltages of the bipolar transistors. In an embodiment, the pn diodes are not zener diodes, and have breakdown voltages that are at least 1.2 times greater than the normal operating voltage of the circuit 100. As will be discussed later in this specification, the circuit 100 may allow for transistors that can be designed with lower drain-to-source or collector-to-emitter breakdown voltages.

The circuit 100 includes a capacitive element 122 that has electrodes coupled to current-carrying terminals of the transistor 112. In a particular embodiment, one electrode of the capacitive element 122 is electrically connected to a current-carrying terminal of the transistor 112, and the other electrode of the capacitive element 122 is electrically connected to the other current-carrying terminal of the transistor 112.

The circuit 100 further includes a capacitive element 142 and a rectifying element 144. The capacitive element 142 has an electrode coupled to a current-carrying terminal of the transistor 132 and another electrode coupled to a cathode of the rectifying element 144, and an anode of the rectifying element 144 is coupled to the other current-carrying element of the transistor 132. In a particular embodiment, one electrode of the capacitive element 142 is electrically connected to a current-carrying terminal of the transistor 132, the other electrode of the capacitive element 142 is electrically connected to the cathode of the rectifying element 144, and the anode of the rectifying element 144 is electrically connected to the other current-carrying terminal of the transistor 132.

The capacitive elements 122 and 142 can be capacitors, and in a particular embodiment, the capacitive elements can include drift regions of the transistors 112 and 132 as electrodes, and a conductive material adjacent to the drift regions of the transistors 112 and 132 as the other electrodes. An embodiment of such a configuration will be discussed later in this specification for the particular case of a lateral insulated gate-field effect transistor. However, a similar relationship can also hold for other types of transistors, including shielded trench insulated gate field-effect transistors. In this later case, the capacitive element can include the vertical drift region as one electrode, and the laterally adjacent trench shield as the other electrode. The rectifying element can also include the contact to the shield material, wherein the shield material has one conductivity type adjacent to the contact and a different conductivity type away from the contact.

The rectifying element 144 can be a zener diode or a Schottky diode having a breakdown voltage that is in a range of 0.25 to 1.00 times the voltage difference between power supply terminals of the circuit 100. For example, if the circuit is to operate with a 12 V difference between the power supply terminals, the zener or Schottky diode may have a breakdown voltage of at least 3 V or no greater than 12 V. If the voltage difference between the power supply terminals is changed, the breakdown voltage of the zener or Schottky diode can scale with the change in the voltage difference.

The circuit 100 can further include an output node 150 that is coupled to current-carrying terminals of the transistors 112 and 132 and a terminal of a load 160. A higher voltage power supply terminal can be coupled to one of the current-carrying terminal of the transistor 112, such as a drain terminal or collector terminal, and an electrode of the capacitive element 122. A lower voltage power supply terminal can be coupled to one of the current-carrying terminals of the transistor 132, such a source terminal or an emitter terminal, the anode of the rectifying element 144, and another terminal of the load 160. In a particular embodiment, the lower voltage power supply may be electrically connected to ground or 0 volts.

With power devices, such as a high frequency power converter, parasitic characteristics of the circuit can be significant. Even a wire or other interconnect between electronic components within the circuit 100 may cause an issue such as voltage overshoot during switching operations. The parasitic characteristics between the output node 150 and each of the current-carrying terminals of the transistors 112 and 132 and the terminal of the load 160 may be significant. For ease of understanding the concepts described herein, the circuit 100 may be modeled using a serial combination of a resistive element 192 and an inductive element 194 between the output node 150 and a current-carrying terminal of the transistor 112, such as the source terminal.

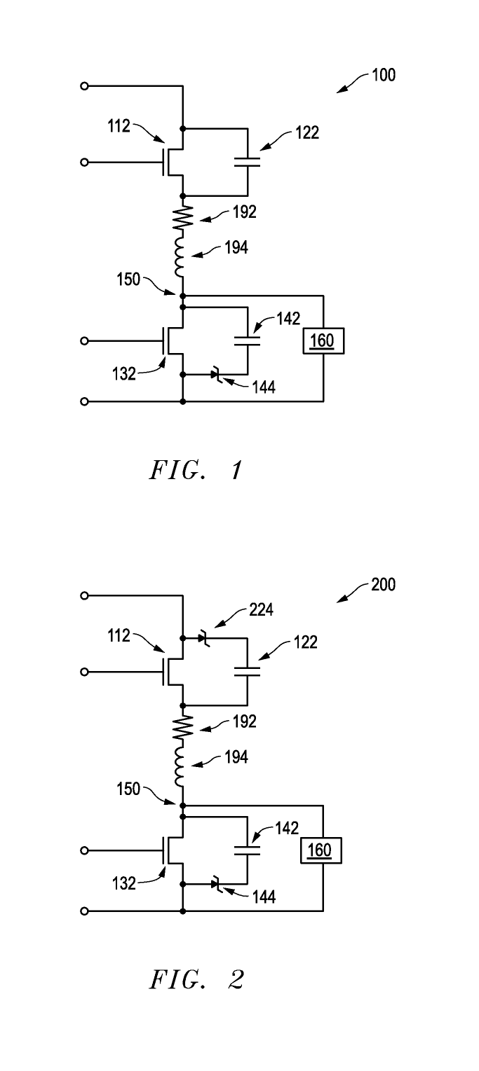

FIG. 2 illustrates an alternative embodiment that includes a circuit 200 that is similar to circuit 100 except that a rectifying element 224 is added. An anode of the rectifying element 224 is coupled to a current-carrying terminal of the transistor 112, and a cathode of the rectifying element 224 is coupled to an electrode of the capacitive element 122. In a particular embodiment, the anode of the rectifying element 224 is electrically connected to a current-carrying terminal of the transistor 112, such as the drain terminal or the collector terminal of the transistor 112, and the cathode of the rectifying element 224 is electrically connected to the electrode of the capacitive element 122. The rectifying element 224 may be a zener or a Schottky diode and have a breakdown voltage in a range as previously described with respect to the rectifying element 144. The rectifying elements 144 and 224 may have the same or different breakdown voltages.

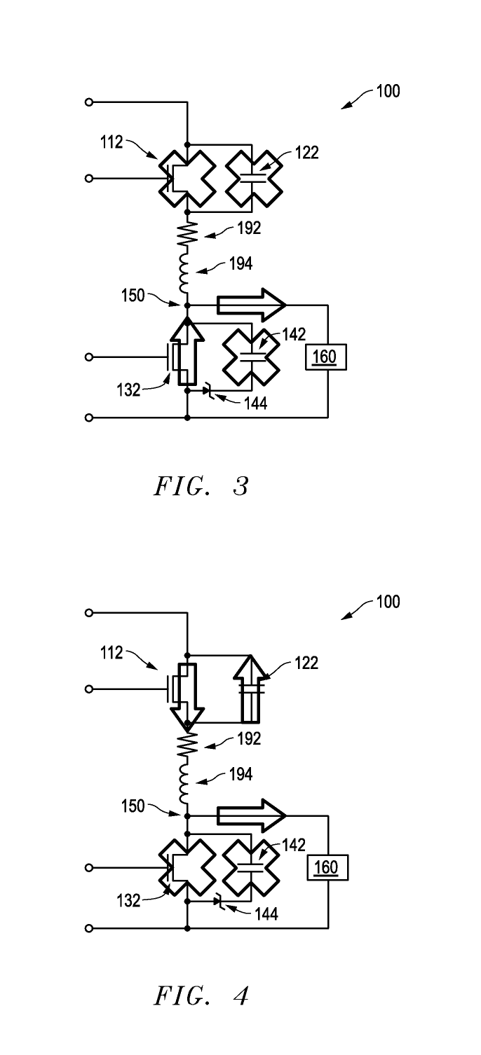

The operation of the circuit 100 is described with respect to FIGS. 3 to 8. The operation of the circuit 200 will be addressed after describing the operation of the circuit 100. The operation described herein is normal and does not reflect an abnormal operation.

FIG. 3 illustrates where current is flowing (as illustrated by arrows) and is not flowing (as illustrated by Xs). FIG. 3 represents the circuit 100 when the high-side switch is off and the low-side switch is on during the quiescent low state (after voltage switching and transient effects have subsided). Current flows through the low-side transistor 132 and to the load 160. No current is flowing through the high-side transistor 112 or to (accumulating charge) or from (dissipating charge) the capacitive elements 122 and 142.

FIG. 4 corresponds to an operating point at the beginning of the leading or rising edge of a switching cycle. The low-side transistor 122 is turned off and (usually after a small dead-time) the high-side transistor 112 is turned on. Current flows through the high-side transistor 112 and to the load 160. Some of the energy that is stored in the capacitive element 122 is dissipated as it is discharged through the high-side transistor 112. Voltage at output node 150 rises as the output capacitance of the low-side transistor 132 charges. No current flows through the low-side transistor 132 because it is off. The capacitive element 142 does not charge initially because the flow of current to the lower power supply terminal is blocked by the rectifying element 144. Therefore, the power-supply-side electrode of the capacitive element 142, the output-node electrode of the capacitive element 142, and the output node are all at approximately the same voltage.

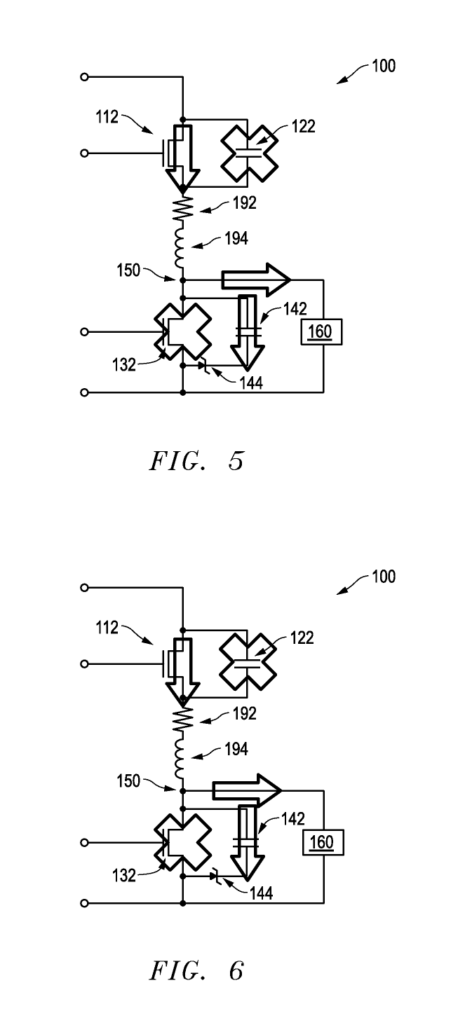

FIG. 5 corresponds to an operation point later during the same leading or rising edge of the switching cycle. The high-side transistor 112 remains on, and current continues to flow through the high-side transistor 112 to the load 160. The voltage of the switching-node electrode of the capacitive element 142 continues to rise as the output capacitance of the low-side transistor 132 charges. Once the reverse breakdown voltage of the rectifying element 144 is reached, the voltage of the power-supply-side electrode of the capacitive element 142 clamps at the breakdown voltage of the rectifying element 144. At this time, the capacitive element 142 begins to charge now that current can flow to ground. The energy that is being dissipated in rectifying element 144 can help to damp the circuit and reduce the magnitude of the subsequent voltage overshoot.

FIG. 6 corresponds to an operation point during the overshoot of the switching cycle when the circuit 100 is in the high state. Current flows through the high-side transistor 112 to the load 160. Because of the charging of the output capacitance of the low-side transistor 132, the current from the power supply exceeds the current needed by the load 160. The parasitic inductance of the inductive element 194 causes the voltage of the output node to rise above the voltage of the power supply. The capacitive element 142 continues to charge as long as the voltage of the power-supply-side electrode of the capacitive element 142 is above the reverse breakdown voltage of the rectifying element 144. The energy that is being dissipated in the rectifying element 144 can continue to help dampen the circuit 100 and reduce the magnitude of the voltage overshoot.

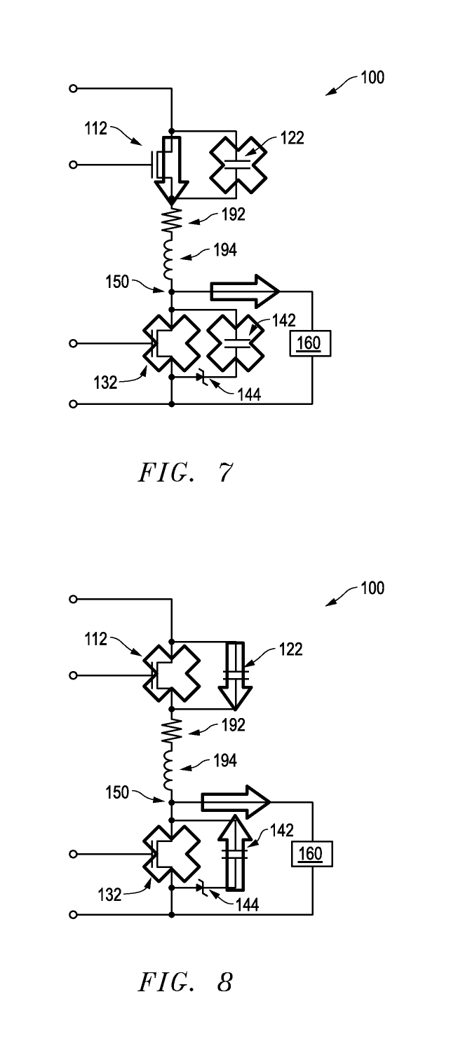

FIG. 7 corresponds to an operation point during the on-state of the switching cycle when the circuit 100 is in the quiescent high state. Current flows through the high-side transistor 112 to the load 160. The output node is approximately at the high-side power supply voltage. The power-supply-side electrode of the capacitive element 142 is somewhere between the reverse breakdown voltage of the rectifying element 144 and the lower power supply voltage. The rectifying element 144 blocks the flow of current through the capacitive element 142.

FIG. 8 corresponds to an operation point during the trailing or falling edge of a switching cycle, when the high-side transistor 112 is turned off. Current flows from the capacitance of the high-side and low-side transistors 112 and 132. (The high-side is charging, and the low-side is discharging.) The output node rapidly falls because there is no longer any current coming from the power supply terminals. The capacitive elements 122 and 142 discharge and supply the energy that was stored within such capacitive elements. Because there is no rectifying element between the capacitive element 142 and the output node 150 and the rectifying element 144 is in its forward conduction mode, the power loss due to series resistance is reduced during the discharge of the capacitive elements 122 and 142.

The operation of the circuit 200 in FIG. 2 would be similar except that the zener or Schottky diode 224 when turning on the low-side transistor 132 acts in a similar manner as the zener or Schottky diode 142 when turning on the high-side transistor 112.

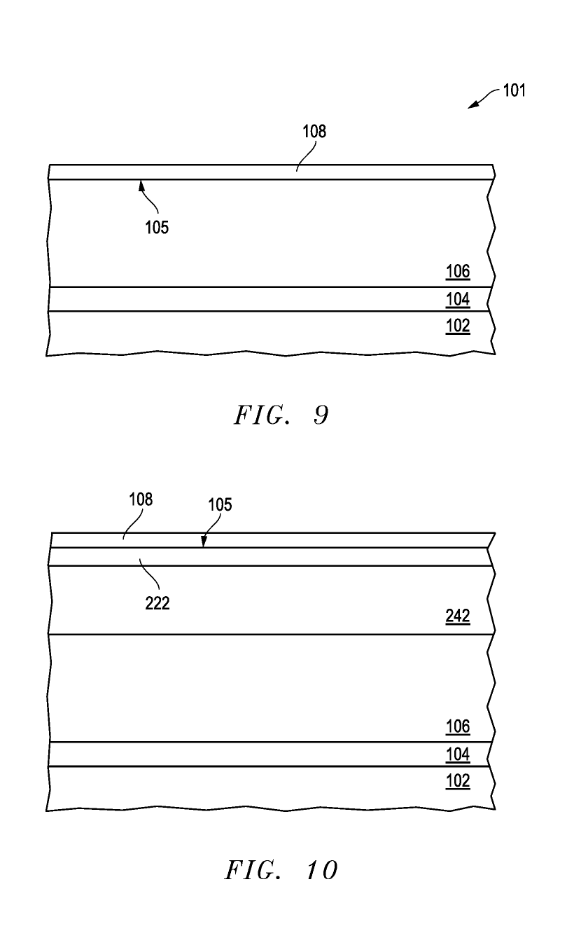

FIGS. 9 to 20 illustrate an exemplary process of forming transistor structures for the low-side transistor 132, capacitors for the capacitive element 142, and zener or Schottky diodes for the rectifying element 144 of the circuits illustrated in FIGS. 1 and 2. The formation of the high-side transistor 112 (FIGS. 1 and 2), the capacitive element 122 (FIGS. 1 and 2), and the rectifying element 224 (FIG. 2) will be formed in a similar manner.

FIG. 9 includes an illustration of a cross-sectional view of a portion of a workpiece 101 that includes a buried conductive region 102, a buried insulating layer 104, a semiconductor layer 106, and a dielectric layer 108. The buried conductive region 102 can include a Group 14 element (i.e., carbon, silicon, germanium, or any combination thereof) and can be heavily n-type or p-type doped. For the purposes of this specification, heavily doped is intended to mean a peak dopant concentration of at least approximately 1×10¹⁹ atoms/cm³, and lightly doped is intended to mean a peak dopant concentration of less than approximately 1×10¹⁹ atoms/cm³. The buried conductive region 102 can be a portion of a heavily doped substrate (e.g., a heavily n-type doped wafer) or may be a buried doped region disposed over a substrate of opposite conductivity type or over another buried insulating layer (not illustrated) that is disposed between a substrate and the buried conductive region 102. In an embodiment, the buried conductive region 102 is heavily doped with an n-type dopant, such as phosphorus, arsenic, antimony, or any combination thereof. In a particular embodiment, the buried conductive region 102 includes arsenic or antimony if diffusion of the buried conductive region 102 is to be kept low, and in a particular embodiment, the buried conductive region 102 includes antimony to reduce the level of autodoping (as compared to arsenic) during formation of a subsequently-formed semiconductor layer.

The buried insulating layer 104 is disposed over the buried conductive region 102. During normal operation, the buried insulating layer 104 helps to isolate the voltage on the buried conductive region 102 from portions of the semiconductor layer 106. The buried insulating layer 104 can include an oxide, a nitride, or an oxynitride. The buried insulating layer 104 can include a single film or a plurality of films having the same or different compositions. The buried insulating layer 104 can have a thickness in a range of at least approximately 0.2 micron or at least approximately 0.3 micron. Further, the buried insulating layer 104 may have a thickness no greater than approximately 5.0 microns or no greater than approximately 2.0 microns. In a particular embodiment, the buried insulating layer 104 has a thickness in a range of approximately 0.5 micron to approximately 0.9 micron. The buried insulating layer 104 is not required, and in another embodiment, the semiconductor layer 106 can be formed on the buried conductive region 102.

The semiconductor layer 106 is disposed over the buried insulating layer 104 and has a primary surface 105 where the transistors and other electronic components (not illustrated) are formed. The semiconductor layer 106 can include a Group 14 element and any of the dopants as described with respect to the buried conductive region 102 or dopants of the opposite conductivity type. In an embodiment, the semiconductor layer 106 is a lightly doped n-type or p-type epitaxial silicon layer having a thickness in a range of approximately 0.2 micron to approximately 5.0 microns, and a doping concentration no greater than approximately 1×10¹⁷ atoms/cm³, and in another embodiment, a doping concentration of at least approximately 1×10¹⁴ atoms/cm³. The semiconductor layer 106 may be disposed over all of the workpiece 101. The dopant concentration within the semiconductor layer 106 as formed or before selectively doping regions within the semiconductor layer 106 will be referred to as the background dopant concentration.

The dielectric layer 108 can be formed over the semiconductor layer 106 using a thermal growth technique, a deposition technique, or a combination thereof. The dielectric layer 108 can include an oxide, a nitride, an oxynitride, or any combination thereof. In an embodiment, the dielectric layer 108 includes an oxide and has a thickness in a range of approximately 11 nm to approximately 50 nm.

FIG. 10 illustrates the workpiece after forming horizontally-oriented doped regions 222 and resurf regions 242, wherein one of each is illustrated in FIG. 10. Within a power transistor being formed, the horizontally-oriented doped regions 222 can be at least part of a drain region of a transistor. The horizontally-oriented doped regions 222 can have a dopant concentration of less than approximately 1×10¹⁹ atoms/cm³ and at least approximately 1×10¹⁶ atoms/cm³ and a depth in one embodiment of less than approximately 0.9 micron, and in another embodiment of less than approximately 0.5 micron. In a particular embodiment, the horizontally-oriented doped regions 222 are n-type doped.

The resurf regions 242 can help keep more current flowing through the horizontally-oriented doped regions 222 instead of into the semiconductor layer 106 underlying the horizontally-oriented doped regions 222. The resurf regions 242 may have a dopant concentration of no greater than approximately 5×10¹⁷ atoms/cm³ and at least approximately 1×10¹⁶ atoms/cm³, and a depth in one embodiment of less than approximately 1.5 microns, and in another embodiment of less than approximately 1.2 microns. The peak concentration of the resurf regions 242 may be in a range of approximately 0.5 micron to approximately 0.9 micron below the primary surface 105. In a particular embodiment, the resurf regions 242 are p-type doped.

In an embodiment, the horizontally-oriented doped regions 222 can be formed before the resurf regions 242. In another embodiment, the horizontally-oriented doped regions 222 can be formed after the resurf regions 242.

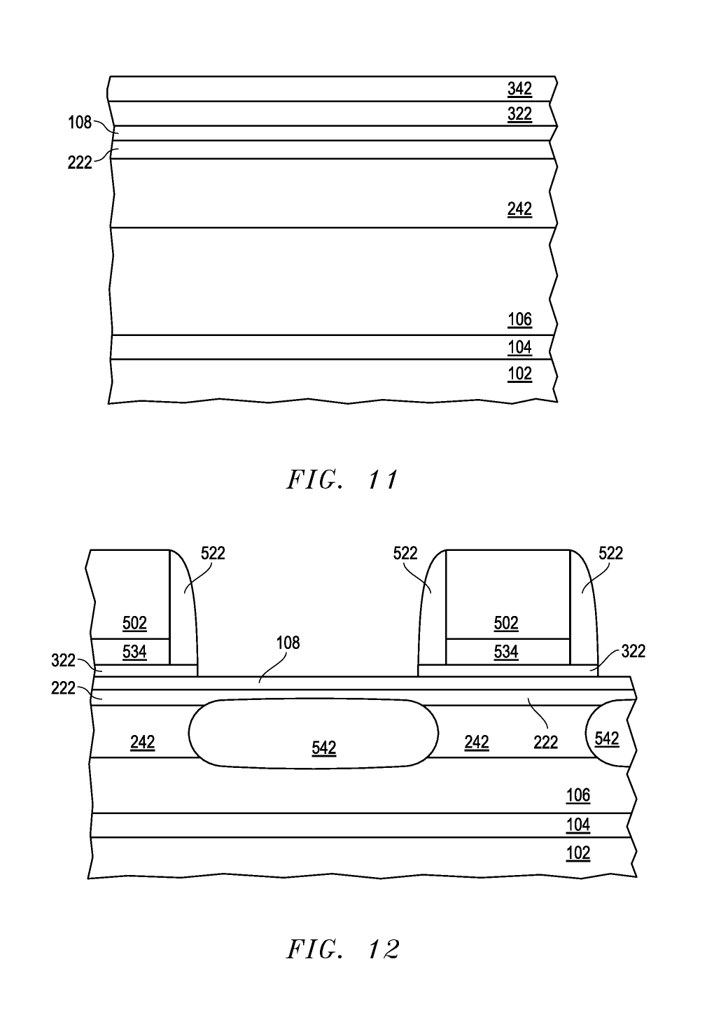

FIG. 11 includes an illustration after forming an insulating layer 322 and a conductive layer 342. The insulating layer 322 can be formed using a thermal growth technique, a deposition technique, or a combination thereof. The insulating layer 322 can include an oxide, a nitride, an oxynitride, or any combination thereof. In an embodiment, the insulating layer 322 includes a nitride and has a thickness in a range of approximately 20 nm to approximately 90 nm. The conductive layer 342 is deposited over the insulating layer 322. The conductive layer 342 includes a conductive material or may be made conductive, for example, by doping. More particularly, the conductive layer 342 can include a doped semiconductor material (e.g., heavily doped amorphous silicon, polysilicon, etc.). The conductive layer 342 has a thickness in a range of approximately 0.05 micron to approximately 0.5 micron. In a particular embodiment, the conductive layer 342 will be used to form parts of the power-supply-side electrodes for the capacitors of capacitive element 142.

FIG. 12 includes an illustration after forming an insulating layer 502, patterning the insulating layer 502, patterning the conductive layer 342 to form conductive electrode members 534, and forming insulating spacers 522 and deep body doped regions 542. The insulating layer 502 can be formed by forming one or more insulating layers. In the embodiment as illustrated in FIG. 12, an insulating layer 502 is deposited over the conductive layer 342. The insulating layer 502 can include an oxide, a nitride, an oxynitride, or an organic dielectric. The insulating layer 502 has a thickness in a range of approximately 0.2 micron to approximately 2.0 microns.

A masking layer (not illustrated) is formed over the insulating layer 502 and patterned to define an opening where the transistor is being formed. Portions of the conductive layer 342 are patterned, and the masking features are removed. Remaining portions of the conductive layer 342 are conductive electrode members 534 that can help to reduce drain-to-gate capacitance in the transistor. In a particular embodiment, the conductive electrode members 534 are horizontally-oriented semiconductor members. The insulating spacers 522 are formed along the sidewalls of the conductive electrode members 534 and the insulating layer 502. In a particular embodiment, the insulating spacers 522 include a nitride and are formed by depositing a nitride layer to a thickness in a range of approximately 20 nm to approximately 90 nm and anisotropically etching the nitride layer to form the insulating spacers 522. Openings defined by the insulating spacers 522 are disposed over portions of the semiconductor layer 106 where deep body doped regions 542 and source and channel regions will be formed.

The deep body doped regions 542 can provide alternative paths during avalanche breakdown between the drain region of the transistor and the deep body doped regions 542 as opposed to avalanche breakdown between the drain region and a subsequently-formed channel region. Thus, if avalanche breakdown involving the drain region would occur, current flows through the deep body doped regions 542 in preference to the channel region. Therefore, the channel region is less likely to be permanently altered if avalanche breakdown occurs. The depths and concentrations of the deep body doped regions 542 may be related to the depths and concentrations of the channel region.

In an embodiment, the peak concentration of the deep body doped regions 542 is at least approximately 0.1 micron deeper than the peak concentration of the channel region, and in another embodiment, the peak concentration of the deep body doped regions 542 is no greater than approximately 0.9 micron deeper than the peak concentration of the channel region. In a further embodiment, the peak concentration of the deep body doped regions 542 is in a range of approximately 0.6 micron to approximately 1.1 microns below the primary surface 105. The deep body doped regions 542 can be formed using a single implant or a combination of implants. The deep body doped regions 542 may or may not contact the buried insulating layer 104. For a single implant or for the implant (of a combination of implants) having the lowest projected range, the dose can be in a range of approximately 5×10¹³ ions/cm² to approximately 5×10¹⁴ ions/cm².

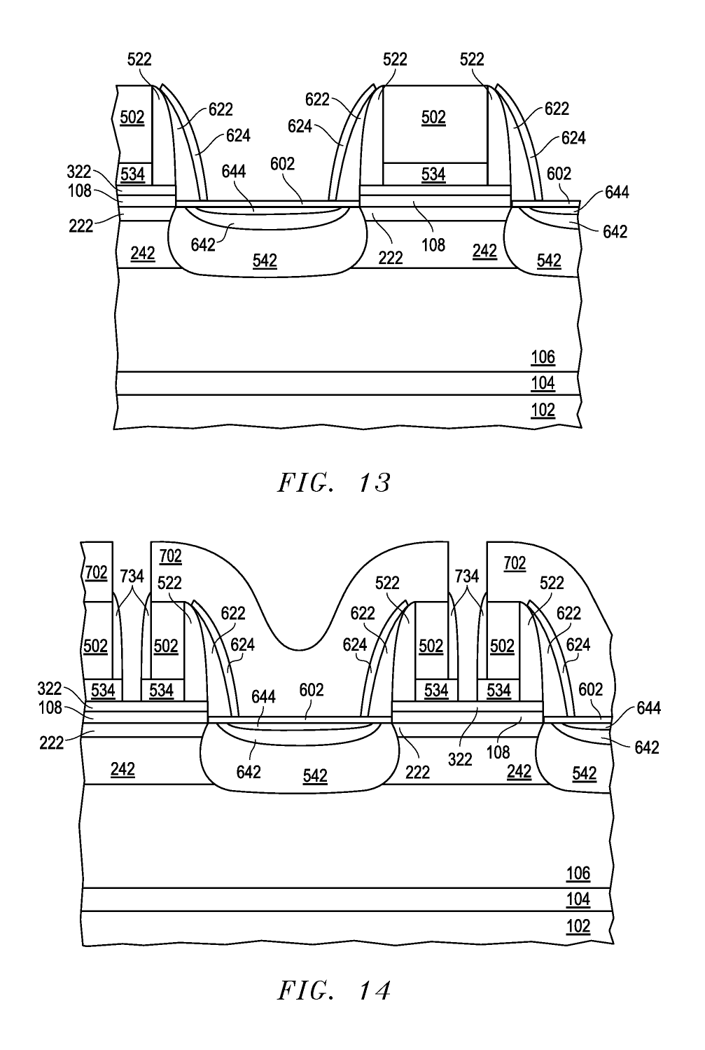

FIG. 13 includes an illustration of the workpiece after forming a gate dielectric layer 602, gate electrodes 622, an insulating layer 624 along exposed surfaces of the gate electrodes 622, body regions 642, and source regions 644. The body regions 642 may include channel regions for the transistor. The body regions 642 can reduce the likelihood of punchthrough between the source and drain of the transistor structures. The body regions 642 have the same conductivity type as the channel region and the deep body doped regions 542 and can have a peak dopant concentration of at least approximately 1×10¹⁸ atoms/cm³. In another embodiment, not illustrated, a channel region for the transistor may be formed separately, and in such an embodiment, the body regions 642 reduces the likelihood of having more resistive regions between the channel region and the deep body doped regions 542, as compared to not having the body regions 642. Such channel regions can be formed by ion implantation with a dose in a range of approximately 5×10¹² ions/cm² to approximately 5×10¹³ ions/cm². The energy can be selected to achieve a projected range of approximately 0.05 micron to approximately 0.3 micron. In another embodiment, one or more implants can be used to tailor the dopant concentrations and profiles under or spaced apart from the gate electrodes 622 to achieve a desire threshold voltage, channel-to-drain breakdown voltage, or other electrical characteristic. After reading this specification, skilled artisans will be able to determine dopant steps, doses, and projected ranges to achieve proper dopant concentrations and locations of doped regions for a particular application.

The exposed portions of the dielectric layer 108 are removed by etching, and the gate dielectric layer 602 is formed over the exposed surface along the bottoms of the openings. In a particular embodiment, the gate dielectric layer 602 includes an oxide, a nitride, an oxynitride, or any combination thereof and has a thickness in a range of approximately 5 nm to approximately 50 nm. The gate electrodes 622 are disposed over the gate dielectric layer 602 and are spaced apart and electrically isolated from the conductive electrode members 534. The gate electrodes 622 can be formed by depositing a layer of material that is conductive as deposited or can be subsequently made conductive. The layer of material can include a metal-containing or semiconductor-containing material. In an embodiment, the layer is deposited to a thickness of approximately 0.1 micron to approximately 0.5 micron. The layer of material is etched to form the gate electrodes 622. In the illustrated embodiment, the gate electrodes 622 are formed without using a mask and have shapes of sidewall spacers. The widths of the gate electrodes 622 at their bases are substantially the same as the thickness of the layer as deposited.

The insulating layer 624 can be thermally grown from the gate electrodes 622 or may be deposited over the workpiece. The thickness of the insulating layer 624 can be in a range of approximately 10 nm to approximately 30 nm. The source regions 644 are formed from portions of the body regions 642. The source regions 644 can include extension portions and a heavily doped portion. The extension portions can have a dopant concentration higher than approximately 5×10¹⁷ atoms/cm³ and less than approximately 5×10¹⁹ atoms/cm³. If needed or desired, an additional set of insulating spacers (not illustrated) may be formed before forming the heavily doped portions of the source regions 644. Such insulating spacers are formed to cover parts of the extension portions of the source regions 644 and to displace the heavily doped portions further from the gate electrodes 622. The insulating spacers can be formed by depositing an insulating layer and anisotropically etching the insulating layer. The insulating spacers can include an oxide, a nitride, an oxynitride, or any combination thereof, and have widths at the bases of the insulating spacers in a range of approximately 50 nm to approximately 200 nm.

The doping for the heavily doped portions of the source regions 644 can be performed after the insulating layer 624 is formed. The heavily doped portions of the source regions 644 allow ohmic contacts to be subsequently made and have a dopant concentration of at least approximately 1×10¹⁹ atoms/cm³. The source regions 644 can be formed using ion implantation, have an opposite conductivity type as compared to the body regions 642, and the same conductivity type as the horizontally-oriented doped regions 222 and the buried conductive region 102.

FIG. 14 includes an illustration of the workpiece after forming an interlevel dielectric (ILD) layer 702 and the conductive electrode members 734. The ILD layer 702 is formed over the workpiece and can include an oxide, a nitride, an oxynitride, an organic dielectric, or any combination thereof. The ILD layer 702 can include a single film having a substantially constant or changing composition (e.g., a high phosphorus content further from the semiconductor layer 106) or a plurality of discrete films. An etch-stop film, an antireflective film, or a combination may be used within or over the ILD layer 702 to help with processing. The ILD layer 702 can be deposited to a thickness in a range of approximately 0.5 micron to approximately 2.0 microns. In the embodiment as illustrated in FIG. 14, the ILD layer 702 is not planarized. In another embodiment, the ILD layer 702 may be planarized if needed or desired. A patterned masking layer (not illustrated) is formed over the workpiece and defines openings under which openings in the ILD layer 702 will be subsequently formed. Exposed portions of the ILD layer 702 are etched to define the openings in which the conductive electrode members 734 will be subsequently formed. Etching may be continued to etch through the conductive members 534. The patterned masking layer can be removed at this time.

The conductive electrode members 734 are formed along the sidewalls of the openings as illustrated in FIG. 14. The conductive electrode members 734 can include a dopant used in forming the zener diodes. If a zener diode is to be formed, the conductive electrode members 734 can be vertically-oriented semiconductor members having a conductivity type opposite that of the conductive layer 342, which corresponds to the conductive members 534 at this point in the process. If a Schottky diode is to be formed, the conductive electrode members 734 can be vertically-oriented semiconductor members having a doping concentration significantly less than that of the conductive layer 342, with a conductivity of either dopant type. In this case the horizontally-oriented conductive members 534 will be heavily doped, and the vertically-oriented semiconductor members will be lightly doped. If no zener or Schottky diode is to be formed, such as on the high-side components of the circuit 100 in FIG. 1, the conductive electrode members 734 can have the same conductivity type as the conductive layer 342, which corresponds to the conductive members 534. Further, when forming the high-side components of circuit 100, the conductive electrode members 734 can include a doped semiconductor material (e.g., heavily doped amorphous silicon, polysilicon, etc.), a metal-containing material (a refractory metal, a refractory metal nitride, a refractory metal silicide, etc.), or any combination thereof.

With respect to forming the zener diode, the conductive electrode members 734 can be formed by depositing a layer of any of the materials as previously described with respect to the conductive layer 342. As compared to the conductive layer 342, the layer for the conductive electrode members 734 has either a different conductivity type, a significantly lower doping concentration, or both. The layer can be doped as deposited or may be doped after deposition. In the case of a Schottky diode, the layer can be deposited undoped with the doping coming from out-diffusion from conductive layer 342 during subsequent thermal processing. The layer for the conductive electrode members 734 fills only part, and not all, of the openings and can have a thickness in a range of approximately 50 nm to approximately 400 nm. If the layer has not been doped, it may be doped at this time. If ion implantation is used, the ion implant may be performed using a tilt angle to incorporate some of the dopant along the vertical or steeper portions of the layer. In a particular embodiment, the tilt angle may be in a range of 5° to 20°. The workpiece may be rotated during different parts of the implantation to ensure better that all surfaces of the conductive electrode members 734 are doped. The amount of dopant in the layer may depend on the reverse bias breakdown voltage of the zener diode. A higher dopant concentration decreases the breakdown voltage, and a lower dopant concentration increases the breakdown voltage. If needed or desired, the dopant may be introduced around the time the contact openings are formed. Turning to the embodiment as illustrated, the layer is anisotropically etched to remove portions of the layer overlying the ILD layer 702. The etch can be continued to recess the uppermost points of the conductive electrode members 734 within the openings. Any exposed portion of conductive members 534 remaining within the openings may also be removed at this time.

Some features of the electronic device at this point in the process are noteworthy. The conductive electrode members 534 and 734 abut each other. In the embodiment as illustrated, each pair of the conductive electrode members 534 and 734 is substantially L-shaped. As illustrated in FIG. 14, the conductive electrode members 734 lie closer to particular ends of the conductive electrode members 534, and the gate electrodes 622 lie closer to opposite ends of the conductive electrode members 534. Thus, the gate electrodes 622 are closer to the conductive electrode members 534 than to the conductive electrode members 734. Thus, capacitive coupling between the gate electrodes 622 and the conductive electrodes can be reduced, as compared to having the conductive electrode members 734 along both ends of the conductive electrode members 534. As compared to distal ends of the conductive electrode members 734, proximal ends of the conductive electrode members 734 are closer to the semiconductor layer 106 and the conductive electrode members 534. Subsequently-formed contact openings will extend to the conductive electrode members 734, and in an embodiment, no contact openings will extend to the conductive electrode members 534. Furthermore, with respect to the buried conductive region 102, an upper portion of conductive electrode member 734 is at a higher elevation than conductive electrode member 534. Also, again with respect to the buried conductive region 102, an upper portion of the gate electrode 622 is at a higher elevation than conductive electrode member 534, and a portion of both conductive electrode member 734 and a portion of gate electrode 622 are at a same elevation that is higher than the highest elevation of conductive electrode member 534.

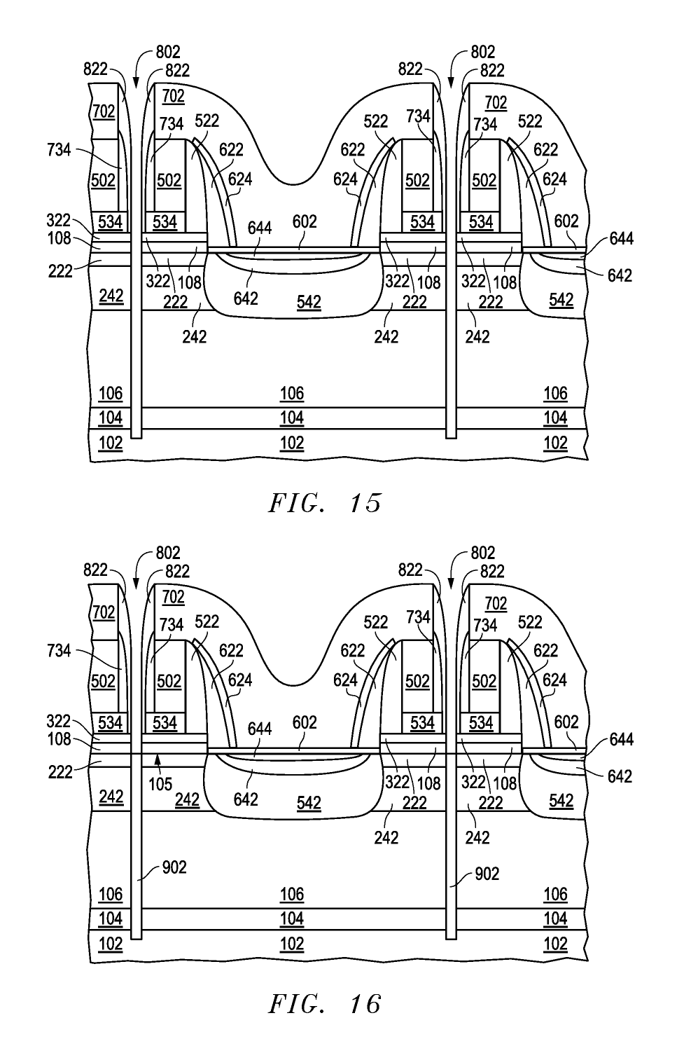

FIG. 15 includes an illustration of the workpiece after forming insulating spacers 822 and trenches 802. The insulating spacers 822 can be formed using any of the materials and formation techniques as previously described with respect to the insulating spacers 522. The insulating spacers 822 can be wider to allow for a sufficiently high enough breakdown voltage between the conductive electrode members 734 and subsequently-formed conductive plugs formed within the trenches. In an embodiment, the layer can be deposited to a thickness in a range of approximately 110 nm to approximately 400 nm. Part of the exposed ILD layer 702 along its uppermost surface may be etched when forming the insulating spacers 822.

Portions of the insulating layer 322, the dielectric layer 108, the horizontally-oriented doped regions 222, the resurf regions 242, the semiconductor layer 106, and the buried insulating layer 104 are patterned to define trenches 802 that expose portions of the buried conductive region 102. In an embodiment, patterning can be formed using anisotropic etching. Part of the exposed ILD layer 702 along its uppermost surface may be etched when etching the insulating layer 322, the dielectric layer 108, the buried insulating layer 104, or any combination thereof. If needed or desired, etching can be continued to etch a portion of the buried conductive region 102. In an embodiment, the trenches 802 may extend in a range of approximately 0.2 micron to 5 microns into the buried conductive region 102, and in a particular embodiment, the trenches 802 may extend in a range of approximately 0.3 micron to 2 microns into the buried conductive region 102. In an embodiment, the width of each of the trenches 802 is in a range of approximately 0.05 micron to 2 microns, and in a particular embodiment, the width of each of the trenches 802 is in a range of approximately 0.1 micron to approximately 1 micron. Dimensions of the trenches 802 may be the same or different from each other.

In a further embodiment, the buried insulating layer 104 may not be present. The trenches 802 may extend completely or only partly to the buried conductive region 102. If the trenches 802 extent only partly, and not completely, to the buried conductive region 102, bottoms of the trenches 802 may be doped to ensure portions of the semiconductor layer 106 along the bottoms of the trenches are electrically connected to the buried conductive region 102.

A conductive layer is formed over the ILD layer 702 and within the trenches 802, and, in a particular embodiment, the conductive layer substantially completely fills the trenches 802. The conductive layer can include a metal-containing or semiconductor-containing material. In an embodiment, the conductive layer can include a heavily doped semiconductor material, such as amorphous silicon or polysilicon. In another embodiment, the conductive layer includes a plurality of films, such as an adhesion film, a barrier film, and a conductive fill material. In a particular embodiment, the adhesion film can include a refractory metal, such as titanium, tantalum, tungsten, or the like; the barrier film can include a refractory metal nitride, such as titanium nitride, tantalum nitride, tungsten nitride, or the like, or a refractory metal-semiconductor-nitride, such as TaSiN; and the conductive fill material can include tungsten or tungsten silicide. In a more particular embodiment, the conductive layer can include Ti/TiN/W. The selection of the number of films and composition(s) of those film(s) depends on electrical performance, the temperature of a subsequent heat cycle, another criterion, or any combination thereof. Refractory metals and refractory metal-containing compounds can withstand high temperatures (e.g., melting points of the refractory metals can be at least 1400° C.), may be conformally deposited, and have a lower bulk resistivity than heavily doped n-type silicon. After reading this specification, skilled artisans will be able to determine the composition of the conductive layer to meet their needs or desires for a particular application.

The portion of the conductive layer that is disposed over the ILD layer 702 is removed. The removal can be performed using a chemical-mechanical polishing or blanket etching technique. An etch or other removal operation is performed to recess the conductive layer further into the trenches 802 to form vertical conductive structures 902, as illustrated in FIG. 16. The vertical conductive structures 902 electrically connect the horizontally-oriented doped regions 222 and the buried conductive region 102 to one another. The uppermost elevations of the vertical conductive structures 902 lie at least at the lowest elevations of the horizontally-oriented doped regions 222 immediately adjacent to the trenches 802. As the uppermost elevations of the vertical conductive structures 902 extend to elevations higher than the horizontally-oriented doped regions 222, parasitic capacitive coupling to the conductive electrode members 534 and 734 may become significant. In a particular embodiment, the vertical conductive structures 902 may extend to an elevation no higher than the primary surface 105. None of the vertical conductive structures 902 are covered by the conductive electrode members 534 and 734. From a top view, the vertical conductive structures 902 are between immediately adjacent pairs of conductive electrode members 734. In a finished electronic device, the buried conductive region 102 can provide an electrical connection to the drain of the transistor 132.

The vertical conductive structures 902 are examples of vertical conductive regions. In another embodiment, a different type of vertical conductive region may be used. For example, in an embodiment in which the buried insulating layer 104 is not present, the vertical conductive regions may be the vertical conductive structures 902 or may be formed by doping portions of the horizontally-oriented doped regions 222, resurf regions 242, and semiconductor layer 106 to form heavily doped regions extending from the horizontally-oriented doped regions 222 to the buried conductive region 102. The heavily doped regions have the same conductivity type as the horizontally-oriented doped regions 222 and can have a shape similar to the vertical conductive structures 902. The heavily doped regions may be formed using different implants at different energies, so that a relatively low resistance connection is made between the horizontally-oriented doped regions 222 and the buried conductive region 102. When the vertical conductive structures are replaced by the heavily doped regions, the heavily doped regions may be formed earlier in the process flow.

Heavily doped drain regions include portions of the vertical conducive structures 902, doping diffused from the vertical conductive structures 902 into the horizontally-oriented doped regions 222, or dopant implanted into a portion of the horizontally-oriented doped regions 222 or semiconductor layer 106.

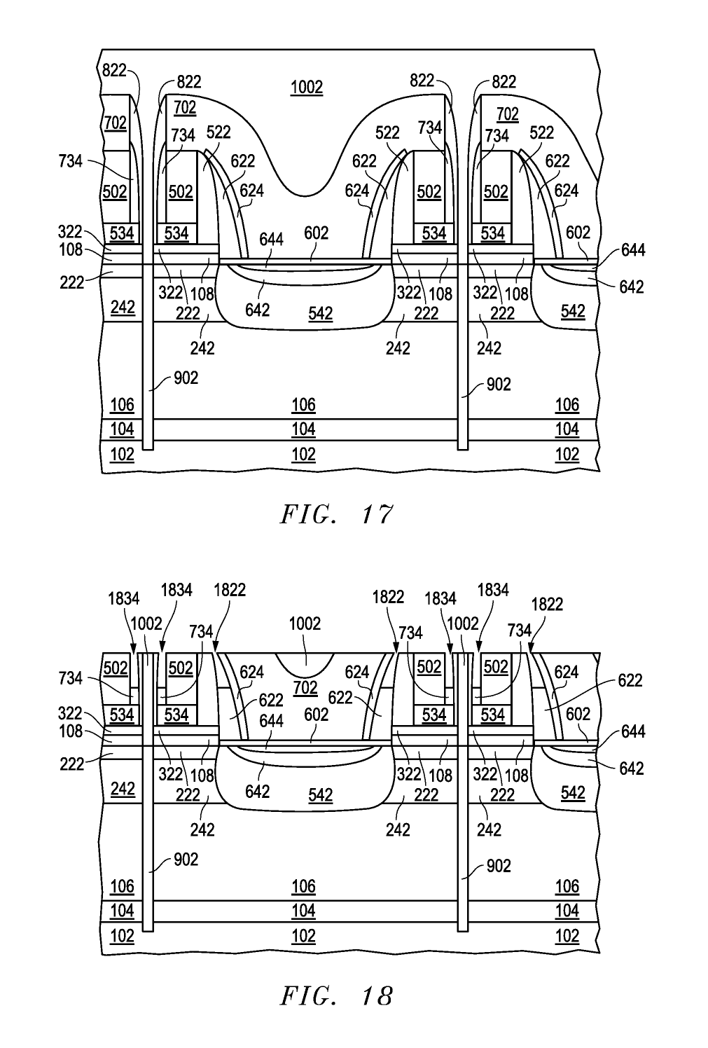

FIG. 17 includes an illustration of the workpiece after forming an ILD layer 1002 over the ILD layer 702. The ILD layer 1002 substantially completely fills remaining portions of the trenches 802. The ILD layer 1002 can include any of the materials, films, and thicknesses as previously described with respect to the ILD layer 702. The ILD layer 1002 can have the same or different materials, films, and thicknesses as compared to the ILD layer 702. The ILD layer 1002 can be planarized if needed or desired.

FIG. 18 includes an illustration after portions of the ILD layers 502, 702 and 1002, the gate electrodes 622, and the conductive electrode members 734 are patterned to define contact openings 1822 and 1834. A non-selective polishing or etchback process can be used until portions of the gate electrodes 622 and conductive electrode members 734 are exposed. A selective etch can be performed to recess the gate electrodes 622 and conductive electrode members 734 to define the contact openings 1822 and 1834. This particular process allows for contact openings to be formed without needing a separate masking operation. If needed or desired, dopant can be introduced into the conductive electrode members 734 to allow for ohmic contacts to the conductive electrode members 734 to be formed, to adjust the breakdown voltage of the zener diode, for another suitable purpose, or any combination thereof.

FIG. 19 includes an illustration of the workpiece after patterning the ILD layers 1002 and 702 and the gate dielectric layer 602 to define an opening 1952 and after forming a heavily doped region 1942. The contact opening 1952 can be defined before or after the other contact openings illustrated and described in FIG. 18. The opening 1952 allows for a source/body contact to be made for the transistor. A patterned masking layer (not illustrated) is formed over the workpiece, and exposed portions of the ILD layers 702 and 1002 and the gate dielectric layer 602 are etched to define the contact opening 1952. Etching is continued to etch through the source regions 644 and expose a portion of the body regions 642 along the bottom of the contact opening 1952. The patterned masking layer can be removed at this time. The bottom of the opening 1952 can be doped to form the heavily doped region 1942, which allows an ohmic contact to be formed to the body regions 642. The heavily doped region 1942 has the same conductivity type as body regions 642 and a dopant concentration of at least 1×10¹⁹ atoms/cm³.

In an embodiment, after defining the contact opening 1952 and before forming the heavily doped region 1942, a sacrificial layer (not illustrated) may be formed along exposed portions of source regions 644 to reduce the likelihood of counterdoping of the source regions 644. If needed or desired, the sacrificial layer may be anisotropically etched along the bottom of the opening 1952. The heavily doped region 1942 may be formed by ion implantation or another suitable doping technique. The workpiece may be annealed to activate the dopants introduced into the workpiece during the contact opening process sequence. After doping and anneal, the sacrificial layer is removed to expose portions of the source regions 644 within the contact opening 1952.

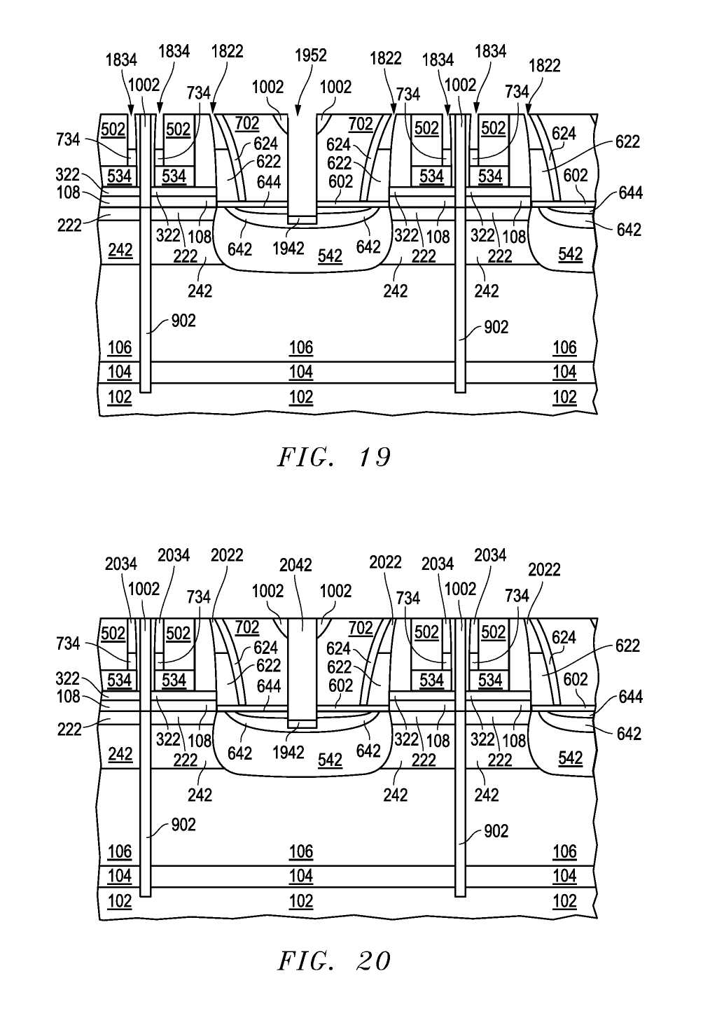

FIG. 20 includes an illustration after forming conductive plugs 2022, 2034, and 2042. The conductive plugs 2022 are electrically connected to the gate electrodes 622 of the transistor, the conductive plugs 2034 are electrically connected to the conductive electrode members 734, and the conductive plug 2042 is electrically connected to the source regions 644 and the body regions 642 of the transistor. In an embodiment, none of conductive plugs within the ILD layer 702 is electrically connected to the horizontally-oriented doped regions 222 or the conductive electrode members 534, as the conductive electrode members 534 have no electrical contact apart from the conductive electrode members 734. A drain for the transistor includes portions of the horizontally-oriented doped regions 222 that are electrically connected to the buried conductive region 102.

In an embodiment, the conductive plugs 2022, 2042, and 2034 can be formed using a plurality of films. In an embodiment, a layer including a refractory metal, such as Ti, Ta, W, Co, Pt, or the like, or another metal-containing material can be deposited over the workpiece and within the openings 1822, 1834, and 1952. If needed or desired, a layer including a metal nitride layer can be deposited over the layer including the refractory metal. The workpiece can be annealed so that portions of the layer including the refractory metal are selectively reacted with exposed silicon, such as substantially monocrystalline or polycrystalline silicon, to form a metal silicide. Thus, portions of the gate electrodes 622, conductive electrode members 734, source regions 644, body regions 642, and heavily doped regions 1942 may react with the metal within the layer that includes the refractory metal to form a metal silicide. In the case where conductive electrode members 734 are lightly doped, this metal silicide will create the electrical barrier for the Schottky diode. Portions of the layer including the refractory metal that contact an insulating layer do not react. A metal nitride layer may be formed to further fill a part, but not the remainder of the openings. The metal nitride layer can act as a barrier layer. A layer of a conductive material fills the remainder of the contact openings 1822, 1834, and 1952. Portions of the layer including the refractory metal, the metal nitride layer and the conductive material that overlies the ILD layer 1002 are removed to form the conductive plugs 2022, 2034, and 2042.

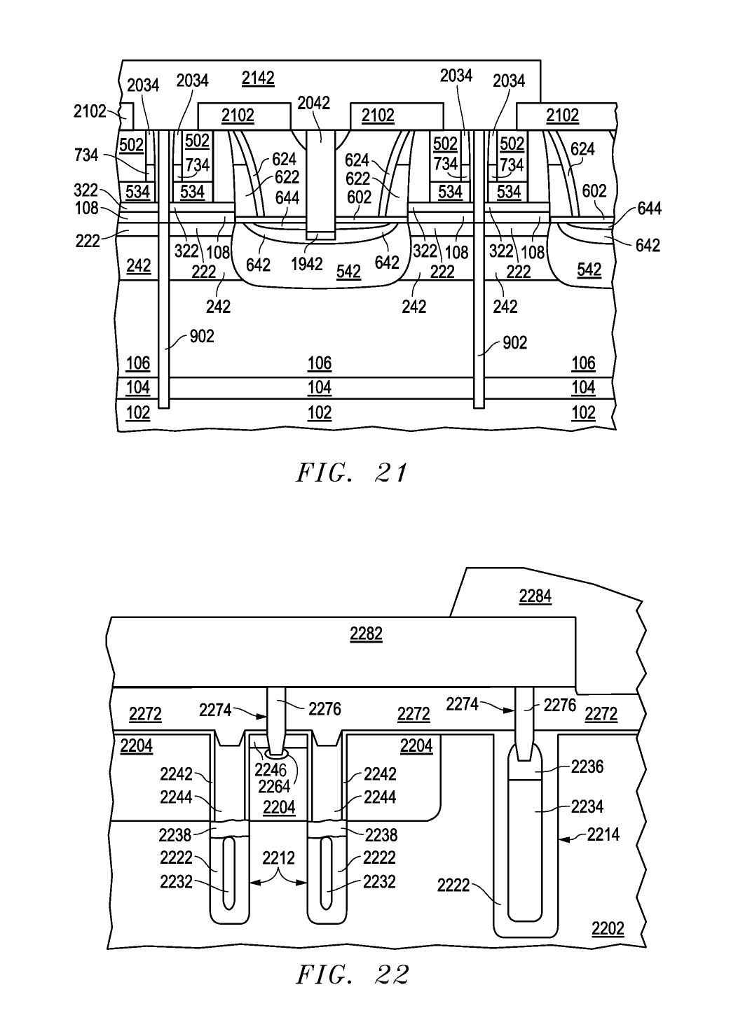

FIG. 21 includes an illustration of the workpiece after a first level of interconnects are formed. An ILD layer 2102 can include any of the compositions as previously described with respect to the ILD layer 702. The ILD layer 2102 can have substantially the same composition or a different composition as compared to the ILD layer 702. The ILD layer 2102 is patterned to define via openings. Interconnect 2142 is formed and extends at least partly within the via openings within the ILD layer 2102. The interconnect 2142 electrically connects the source regions 644 of the transistor and the conductive electrode members 734 to one another, via conductive plugs 2034 and 2042. An interconnect (not illustrated) is electrically connected to the gate electrode 622 via the conductive plug 2022 at a location not illustrated in FIG. 21.

Although not illustrated, additional or fewer layers or features may be used as needed or desired to form the electronic device. Field isolation regions are not illustrated but may be used to help electrically isolate portions of the power transistor. In another embodiment, more insulating and interconnect levels may be used. A passivation layer can be formed over the workpiece or within the interconnect levels. After reading this specification, skilled artisans will be able to determine layers and features for their particular application.

The electronic device can include many other transistor structures that are substantially identical to the transistor structures as illustrated in FIG. 21. The transistor structures can be connected in parallel to each other to form the transistor. Such a configuration can give a sufficient effective channel width of the electronic device that can support the relatively high current flow that is used during normal operation of the electronic device. The transistor can be a power transistor that is well suited for use in power switching applications, such as a high-frequency voltage regulator.

In another embodiment, the field-effect transistor may be a vertical transistor having a trench gate and a vertically-oriented drift region. Furthermore, a conductive electrode member can be formed below the trench gate to provide shielding between the trench gate and the vertically-oriented drift region. In this case, a capacitor structure is formed across the insulating layer between the vertically-oriented drift region and the conductive electrode member below the trench gate.

FIG. 22 illustrates such an embodiment. Many features illustrated in FIG. 22 can be formed using a process as described in more detail in US2010/0123192, which is incorporated herein by reference in its entirety. A lightly doped semiconductor layer 2202 overlies a heavily doped substrate or buried doped region (not illustrated) of the same conductivity type as the lightly-doped semiconductor layer 2202. The heavily doped substrate or buried doped region is connected to a drain terminal for the transistor structure, and the lightly doped semiconductor layer 2202 provides a drift region for the transistor structure. A well region 2204 is formed within the semiconductor layer 2202 and has a conductivity type opposite the conductivity type of the semiconductor layer 2202. A portion of the well region 2204 corresponds to the channel region of the transistor structure.

Portions of the semiconductor layer 2202 and well region 2204 are patterned to define one or more trenches. As illustrated, a trench includes trench portion 2212, which includes a conductive electrode 2232 and the gate electrode 2244, and portion 2214, which includes the surface connection to the conductive electrode 2232.

An insulating layer 2222 is formed within the trench and is filled with a conductive material. The conductive material is recessed within the trench portion 2212 to form the conductive electrode that can be a capacitor electrode for the capacitor 122 or 142 in FIGS. 1 and 2. The conductive material is also recessed within the trench portion 2214 to form the connection portion 2234 for the conductive electrode 2232. An upper part of the connection 2234 is counterdoped to form doped region 2236. The junction between the connection portion and the doped region 2236 is a zener diode that can be used for the rectifying element 144 or 224 (FIGS. 1 and 2). An insulating member 2238 is formed over the conductive electrode 2232.

Any insulating layer along the sidewall of the trench portion 2212 and above the insulating member 2238 is removed, and a gate dielectric layer 2242 is formed along the sidewall of the trench portion 2212. The gate electrode 2244 is formed within the upper part of the trench portion 2212. A source region 2246 is formed from a portion of the well region 2204 and has a conductivity type opposite that of the well region 2204.

An insulating layer 2272 is formed over the workpiece and is pattered to form contact openings 2274. A contact opening for the gate electrode is formed but is not illustrated in FIG. 22. The etch for the conductive openings is continued until the well region 2204 is reached. A portion of the well region 2204 is heavily doped to form a body contact region 2264 having the same conductivity type as the well region 2204. Conductive plugs 2276 are formed within the insulating layer to form electrical connections to the source region 2246 and body contact region 2264 and to the doped region 2236, which is the anode of the zener diode illustrated. An interconnect 2282 electrically connects the source region 2246, the body contact region 2264, and doped region 2236 to one another. Another interconnect (not illustrated) is electrically connected to the gate electrode 2244. A passivation layer 2284 is formed and patterned to exposed part of the interconnect 2282.

In still another embodiment, one or more bipolar transistors may be used instead of the field-effect transistors. In this embodiment, current-carrying electrodes can include emitter regions and collector regions instead of the source regions and drain regions, and control electrodes can include base regions instead of gate electrodes. If a buried collector is used, the buried collector can be patterned to allow a properly isolated connection to be made to the buried conductive region 102.

The rectifying element in the circuit can help to dampen voltage overshoot at an output node of a switching circuit, such as in a high frequency power converter. When the rectifying element is coupled with the low-side components, the rectifying element can temporarily delay energy being stored in the low-side capacitive element immediately after the circuit is put into its high state. After the breakdown voltage of the rectifying element is exceeded, excess energy can be dissipated as avalanche energy in the diode. Thus, the voltage overshoot can be better controlled and allow the low-side transistor to be designed with a lower drain-to-source breakdown voltage, which may allow lower on-state resistance through the low-side transistor when it is on. A similar effect may be seen when the rectifying element is coupled to the high-side components during the transience when switching the circuit to a low state.

The conductive electrode members 734 can allow for the integration of zener diodes with capacitor electrodes for the capacitors 142. The zener diodes lie at the pn junction that is within the conductive electrode members 534, within the conductive electrode members 734, or at the interface between the conductive electrode members 534 and 734. Thus, valuable substrate area is used without increasing the die size.

Many different aspects and embodiments are possible. Some of those aspects and embodiments are described below. After reading this specification, skilled artisans will appreciate that those aspects and embodiments are only illustrative and do not limit the scope of the present invention. Exemplary embodiments may be in accordance with any one or more of the ones as listed below.

### Embodiment 1

A circuit comprising:
a first transistor including a first current-carrying terminal and a second current-carrying terminal;
a first capacitive element including a first electrode and a second electrode, wherein the first electrode is coupled to the first current-carrying terminal of the first transistor; and
a rectifying element including an anode and a cathode, wherein the cathode is coupled to the second electrode of the first capacitive element, and the anode is coupled to the second current-carrying terminal of the first transistor.

### Embodiment 2

The circuit of Embodiment 1, wherein the first transistor is an insulated gate field-effect transistor, and the first current-carrying terminal is a drain terminal, and the second current-carrying terminal is a source terminal.

### Embodiment 3

The circuit of Embodiment 1, wherein the rectifying element is a zener diode or a Schottky diode and has a diode breakdown voltage.

### Embodiment 4

The circuit of Embodiment 3, wherein the diode breakdown voltage is at least 3 V.

### Embodiment 5

The circuit of Embodiment 3, wherein the diode breakdown voltage is no greater than 12 V.

### Embodiment 6

The circuit of Embodiment 3, wherein the diode breakdown voltage is less than a breakdown voltage between the first and second current-carrying terminals of the first transistor.

### Embodiment 7

The circuit of Embodiment 3, wherein the diode breakdown voltage is less than half of a breakdown voltage between the first and second current-carrying terminals of the first transistor.

### Embodiment 8

The circuit of Embodiment 1, further comprising:
a second transistor including a third current-carrying terminal and a fourth current-carrying terminal; and
a second capacitive element including a third electrode and a fourth electrode, wherein:
   the first current-carrying terminal of the first transistor is electrically connected to the first electrode of the first capacitive element and is coupled to an output node;
   the second electrode of the first capacitive element is electrically connected to the cathode of the rectifying element;
   the second current-carrying terminal of the first transistor is electrically connected to the anode of the rectifying element and is coupled to a first power supply terminal;
   the third current-carrying terminal of the second transistor is coupled to a second power supply terminal and the third electrode of the second capacitive element; and
   the fourth current-carrying terminal of the second transistor is electrically connected to the fourth electrode of the second capacitive element and is coupled to the output node.

### Embodiment 9

An electronic device comprising:
a diode comprising:
   a first horizontally-oriented semiconductor member having a first end and a first conductivity type with a first doping concentration;
   a first vertically-oriented semiconductor member having a second end and a second conductivity type with a second doping concentration, and the first end of the first horizontally-oriented semiconductor member physically contacts the second end of the first vertically-oriented semiconductor member, wherein either the second conductivity type is different than the first conductivity type, or the second doping concentration is significantly lower than the first doping concentration, or both; and
   a metal-containing material in contact with the first vertically-oriented semiconductor member.

### Embodiment 10

The electronic device of Embodiment 9, further comprising a semiconductor layer having a primary surface; and an insulating layer disposed between the semiconductor layer and the first horizontally-oriented semiconductor member.

### Embodiment 11

The electronic device of Embodiment 9, further comprising a first transistor, wherein:
the first transistor includes a first doped region in a semiconductor layer; and
a first capacitive element includes a first electrode and a second electrode, wherein the first electrode of the first capacitive element includes the first horizontally-oriented semiconductor member, and the second electrode includes the first doped region.

### Embodiment 12

The electronic device of Embodiment 9, further comprising an electrical contact to the first vertically-oriented semiconductor member.

### Embodiment 13

The electronic device of Embodiment 12, wherein the first horizontally-oriented semiconductor member has no electrical contact apart from the first vertically-oriented semiconductor member.

### Embodiment 14

The electronic device of Embodiment 11, further comprising an insulating layer disposed between the semiconductor layer and the first horizontally-oriented semiconductor member.

### Embodiment 15

The electronic device of Embodiment 14, wherein the first doped region is a horizontally-oriented doped region adjacent to a primary surface of the semiconductor layer and beneath the first horizontally-oriented semiconductor member.

### Embodiment 16

The electronic device of Embodiment 15, further comprising an ohmic contact to the semiconductor layer, wherein the ohmic contact is spaced apart from the first horizontally-oriented semiconductor member and is electrically connected to the electrical contact of the first vertically-oriented semiconductor member.

### Embodiment 17

A process of forming an electronic device comprising:
providing a workpiece including a semiconductor substrate with a primary surface;
forming a first insulating layer over the primary surface;
forming a first semiconductor layer of a first conductivity type over the first insulating layer;
forming a patterned second insulating layer over the first semiconductor layer,
   wherein the patterned second insulating layer defines a first opening; and
   forming a second semiconductor member along a sidewall of the first opening in the patterned second insulating layer,
   wherein in a finished device,
at least a portion of the second semiconductor member has a second conductivity type different from the first conductivity type; and
a diode includes a junction between dopants of the first and second conductivity types within the first semiconductor layer, within the second semiconductor member, or at an interface between the first semiconductor layer and the second semiconductor member.

### Embodiment 18

The process of Embodiment 17, wherein forming the second semiconductor member along the sidewall of the first opening in the patterned second insulating layer comprises conformally depositing a semiconductor material over the surface of the workpiece and within the first opening; and anisotropically etching the semiconductor material to leave a spacer along the sidewall of the first opening in the second insulating layer.

### Embodiment 19

The process of Embodiment 18, wherein anisotropic etching the semiconductor material also removes a portion of the first semiconductor layer that is exposed under the first opening of the second insulating layer.

### Embodiment 20

The process of Embodiment 17, further comprising forming an electrical contact to the second semiconductor member.

### Embodiment 21

The process of Embodiment 20, wherein in the finished device, no electrical contact is made to the first semiconductor layer apart from the electrical contact through the second semiconductor member.

### Embodiment 22

The process of Embodiment 20, wherein forming the electrical contact comprises forming a patterned third insulating layer over the patterned second insulating layer and the second semiconductor member, wherein the patterned third insulating layer defines a second opening that exposes the second semiconductor member; and recessing the second semiconductor member within the second opening.

### Embodiment 23

The process of Embodiment 22, further comprising doping the second conductive member with a dopant having the second conductivity type.

### Embodiment 24

The process of Embodiment 17, further comprising forming a horizontally-oriented doped region within the semiconductor substrate and adjacent to the primary surface, wherein a capacitive element comprises a first electrode and a second electrode, the first electrode includes the horizontally-oriented doped region; and the second electrode includes a portion of the first semiconductor layer.

### Embodiment 25

The process of Embodiment 24, further comprising forming a source region within the first semiconductor layer and adjacent to the primary surface.

### Embodiment 26

The process of Embodiment 25, wherein the source region and the horizontally-oriented doped region have the first conductivity type.

### Embodiment 27

The process of Embodiment 25, further comprising forming a heavily doped drain region directly contacting the horizontally-oriented doped region and having the first conductivity type, wherein a transistor includes the source region, the horizontally-oriented doped region, and the heavily doped drain region.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

1. A circuit comprising:
a first transistor including a first current-carrying terminal and a second current-carrying terminal;
a first capacitive element including a first electrode and a second electrode, wherein the first electrode is coupled to the first current-carrying terminal of the first transistor; and
a rectifying element including an anode and a cathode, wherein the cathode is coupled to the second electrode of the first capacitive element, and the anode is coupled to the second current-carrying terminal of the first transistor
wherein the first current-carrying terminal is a drain terminal, and the second current-carrying terminal is a source terminal.

2. The circuit of claim 1, wherein the first transistor is an insulated gate field-effect transistor.

3. The circuit of claim 1, wherein the rectifying element is a zener diode or a Schottky diode and has a diode breakdown voltage.

4. The circuit of claim 3, wherein the diode breakdown voltage is at least 3 V.

5. The circuit of claim 3, wherein the diode breakdown voltage is no greater than 12V.

6. The circuit of claim 3, wherein the diode breakdown voltage is less than a breakdown voltage between the first and second current-carrying terminals of the first transistor.

7. The circuit of claim 3, wherein the diode breakdown voltage is less than half of a breakdown voltage between the first and second current-carrying terminals of the first transistor.

8. The circuit of claim 1, further comprising:
a second transistor including a third current-carrying terminal and a fourth current-carrying terminal; and
a second capacitive element including a third electrode and a fourth electrode,
wherein:
the first current-carrying terminal of the first transistor is electrically connected to the first electrode of the first capacitive element and is coupled to an output node;
the second electrode of the first capacitive element is electrically connected to the cathode of the rectifying element;
the second current-carrying terminal of the first transistor is electrically connected to the anode of the rectifying element and is coupled to a first power supply terminal;
the third current-carrying terminal of the second transistor is coupled to a second power supply terminal and the third electrode of the second capacitive element; and
the fourth current-carrying terminal of the second transistor is electrically connected to the fourth electrode of the second capacitive element and is coupled to the output node.

9. An electronic device comprising:
the current of claim 1, wherein the rectifying element includes a diode comprising:
a first horizontally-oriented semiconductor member having a first end and a first conductivity type with a first doping concentration;
a first vertically-oriented semiconductor member having a second end and a second conductivity type with a second doping concentration, and the first end of the first horizontally-oriented semiconductor member physically contacts the second end of the first vertically-oriented semiconductor member, wherein either the second conductivity type is different than the first conductivity type, or the second doping concentration is significantly lower than the first doping concentration, or both; and
a metal-containing material in contact with the first vertically-oriented semiconductor member.

10. The electronic device of claim 9, further comprising:
a semiconductor layer having a primary surface; and
an insulating layer disposed between the semiconductor layer and the first horizontally-oriented semiconductor member.

11. The electronic device of claim 9, wherein:
the first transistor includes a first doped region in a semiconductor layer; and
the first electrode of the first capacitive element includes the first horizontally-oriented semiconductor member, and the second electrode includes the first doped region.

12. The electronic device of claim 9, further comprising an electrical contact to the first vertically-oriented semiconductor member.

13. The electronic device of claim 12, wherein the first horizontally-oriented semiconductor member has no electrical contact apart from the first vertically-oriented semiconductor member.

14.-20. (canceled)

21. The circuit of claim 1, wherein the first current-carrying terminal of the first transistor is electrically connected to the first electrode of the first capacitive element and is coupled to an output node.

22. The circuit of claim 1, wherein the second electrode of the first capacitive element is electrically connected to the cathode of the rectifying element.

23. The circuit of claim 1, wherein the second current-carrying terminal of the first transistor is electrically connected to the anode of the rectifying element and is coupled to a first power supply terminal.

24. The electronic device of claim 1, further comprising an insulating layer disposed between the semiconductor layer and the first horizontally-oriented semiconductor member.

25. The electronic device of claim 24, wherein the first doped region is a horizontally-oriented doped region adjacent to a primary surface of the semiconductor layer and beneath the first horizontally-oriented semiconductor member.

26. The electronic device of claim 25, further comprising an ohmic contact to the semiconductor layer, wherein the ohmic contact is spaced apart from the first horizontally-oriented semiconductor member and is electrically connected to the electrical contact of the first vertically-oriented semiconductor member.

27. The electronic device of claim 8, wherein the third current-carrying terminal of the second transistor is electrically connected to the third electrode of the second capacitive element.
